(19) United States
(12) Patent Application Publication
(10) Pub. No.: US 2025/0330149 A1
(43) Pub. Date: Oct. 23, 2025

(54) SILICON-SUPPORTED WAFER TO WAFER SOLDER BOND

(71) Applicant: SKYWORKS SOLUTIONS, INC., Irvine, CA (US)

(72) Inventors: Martha Kennedy Small, Fort Collins, CO (US); Atsushi Takano, Kadoma-Shi (JP)

(21) Appl. No.: 19/181,859

(22) Filed: Apr. 17, 2025

Related U.S. Application Data
(60) Provisional application No. 63/637,454, filed on Apr. 23, 2024.

(51) Int. Cl. H03H 9/46; H03H 3/007; H03H 9/02

(52) U.S. Cl. CPC H03H 9/462; H03H 3/0072; H03H 9/02047

(57) ABSTRACT

Aspects and embodiments disclosed herein relate to a package for an acoustic wave device. The package comprises a cap wafer having a cavity defined in a lower surface thereof, outside walls of the cavity defining inner edges of an inner portion of a seal ring formed integral with the cap wafer, a portion of a layer of a first metal disposed on and around the inner portion of the seal ring, and a device wafer including the acoustic wave device and a layer of a second metal, a portion of the layer of the second metal bonded to the portion of the layer of the first metal to define the seal ring, the cavity surrounding the acoustic wave device and hermetically sealed by the cap wafer, device wafer, and seal ring.

### CROSS-REFERENCE TO RELATED APPLICATIONS

This application claims priority under 35 U.S.C. § 119(e) to U.S. Provisional Patent Application Ser. No. 63/637,454, titled “SILICON-SUPPORTED WAFER TO WAFER SOLDER BOND,” filed Apr. 23, 2024, the entire content of which is incorporated herein by reference for all purposes.

### BACKGROUND

### Technical Field

Embodiments of this disclosure relate to packaging of microelectromechanical systems, for example, acoustic wave resonators.

### Description of Related Technology

Modern electronic devices may contain not only electronic circuit elements but also microelectromechanical systems. Such microelectromechanical systems may include devices such as accelerometers or acoustic wave resonators. Acoustic wave resonators may be combined into acoustic wave filters. Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic wave resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a package for an acoustic wave device. The package comprises a cap wafer having a cavity defined in a lower surface thereof, outside walls of the cavity defining inner edges of an inner portion of a seal ring formed integral with the cap wafer, a portion of a layer of a first metal disposed on and around the inner portion of the seal ring, and a device wafer including the acoustic wave device and a layer of a second metal, a portion of the layer of the second metal bonded to the portion of the layer of the first metal to define the seal ring, the cavity surrounding the acoustic wave device and hermetically sealed by the cap wafer, device wafer, and seal ring.

In some embodiments, the seal ring has a width of between 10 μm and 15 μm.

In some embodiments, the seal ring has a height of between 1 μm and 3 μm.

In some embodiments, the portion of the layer of the first metal and the portion of the layer of the second metal are bonded to one another with transient liquid phase bonds.

In some embodiments, the first metal is Sn and the second metal is Au.

In some embodiments, the cap wafer is formed of Si.

In some embodiments, the package further comprises a support pillar, an inner portion of the support pillar formed integral with the cap wafer and a second portion of the layer of the first metal, the second portion of the layer of the first metal disposed on and around the inner portion of the support pillar, the support pillar extending between the cap wafer and a second portion of the layer of the second metal disposed on the device wafer.

In some embodiments, the package further comprises a seed layer including Ti and Cu disposed on the inner portion of the seal ring between the inner portion of the seal ring and the portion of the layer of the first metal

In some embodiments, the package is included in an acoustic wave filter.

In some embodiments, the acoustic wave filter is included in an electronic module.

In some embodiments, the electronics module is included in an electronic device.

In accordance with another aspect, there is provided a method of packaging an acoustic wave device. The method comprises etching a cavity in a lower surface of a cap wafer, outside walls of the cavity defining edges of an inner portion of a seal ring formed integral with the cap wafer, depositing a portion of a layer of a first metal on and around the inner portion of the seal ring, and bonding the portion of the layer of the first metal to a portion of a layer of a second metal disposed on an upper surface of a device wafer including the acoustic wave device, the bonded portions of the layers of the first metal and second metal defining the seal ring, the cavity surrounding the acoustic wave device and hermetically sealed by the cap wafer, device wafer, and seal ring.

In some embodiments, the seal ring is formed with a width of between 10 μm and 15 μm.

In some embodiments, the seal ring is formed with a height of between 1 μm and 3 μm.

In some embodiments, bonding the portion of the layer of the first metal to the portion of the layer of the second metal includes bonding the portions of the layers of the first and second metals with transient liquid phase bonds.

In some embodiments, the first metal is Sn and the second metal is Au.

In some embodiments, the cap wafer is formed of Si.

In some embodiments, the method further comprises forming a support pillar, an inner portion of the support pillar being formed integral with the cap wafer and a second portion of the layer of the first metal, the second portion of the layer of the first metal deposited on and around the inner portion of the support pillar, the support pillar extending between the cap wafer and a second portion of the layer of the second metal disposed on the device wafer.

In some embodiments, the method further comprises forming an acoustic wave filter including the acoustic wave device.

In some embodiments, the method further comprises forming an electronic module including the acoustic wave filter.

In some embodiments, the method further comprises forming an electronic device including the electronic module.

In some embodiments, the method further comprises depositing a seed layer including Ti and Cu on the inner portion of the seal ring.

In some embodiments, the portion of the layer of the first metal is deposited on the seed layer.

### BRIEF DESCRIPTION OF THE DRAWINGS

Embodiments of this disclosure will now be described, by way of non-limiting example, with reference to the accompanying drawings.

FIG. 1 illustrates an example of a package for an acoustic wave device;

FIG. 2A illustrates an act in forming an example of a package for an acoustic wave device;

FIG. 2B illustrates another act in forming the example of the package for the acoustic wave device;

FIG. 2C illustrates another act in forming the example of the package for the acoustic wave device;

FIG. 2D illustrates another act in forming the example of the package for the acoustic wave device;

FIG. 2E illustrates another act in forming the example of the package for the acoustic wave device;

FIG. 3 is a schematic diagram of a radio frequency ladder filter;

FIG. 4 is a block diagram of an example of a filter module that can include one or more surface acoustic wave resonators according to aspects of the present disclosure;

FIG. 5 is a block diagram of an example of a front-end module that can include one or more filter modules according to aspects of the present disclosure; and

FIG. 6 is a block diagram of an example of a wireless device including the front-end module of FIG. 5.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Consumers continue to demand electronic devices with reduced form factors and/or with increased functionality within a given form factor. The overall size of an electronic device may be influenced by the size of the packaging structures for components utilized in the device. Microelectromechanical system elements, for example, acoustic wave resonators and acoustic wave filters often include moving or vibrating parts. Packages for such elements will typically include a cavity that allows the moving parts of these elements to move or vibrate as intended. The cavity is often hermetically sealed to prevent contaminants from the external environment, for example, dust or moisture from entering the cavity and damaging the microelectromechanical system elements. It has been found desirable to reduce the size of packages for microelectromechanical system elements utilized in consumer electronic devices such as cellular telephones, both in surface area and in height, to either provide for additional functionality to be included in the electronic device for a given form factor or to decrease the form factor of the device.

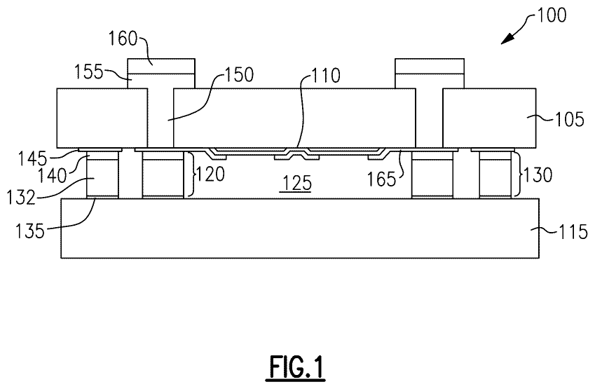

One embodiment of a package for an acoustic wave resonator is illustrated in FIG. 1, indicated generally at 100. The package 100 includes a device wafer 105 on which is formed an acoustic wave device 110, for example, a bulk acoustic wave resonator. A cap wafer 115 is fixed over the device wafer 105 and acoustic wave device 110 by one or more pillars 120 or seal rings 130, referred to hereinafter collectively as standoffs 120, 130. It should be noted that the package 100 is illustrated inverted from the orientation that it would have when mounted in a module, for example, on a laminate substrate, so terms such as “up,” “down,” “over,” and “cap” have their opposite meanings when applied to the package 100 in the orientation illustrated. The standoffs 120, 130 (more specifically, the seal ring(s) 130) form a hermetically sealed cavity 125 between the cap wafer 115 and device wafer 105 that encloses the acoustic wave device 110. The standoffs 120, 130 may be formed of a copper column or ring 132 that was plated onto a seed layer 135 formed of Ti or Ti/Cu alloy deposited on the cap wafer 115. A layer of Sn 140 is plated on the bottom of the copper column or ring 132 and is used to bond the copper column or ring 132 and in turn, the cap wafer 115 to Au pads 145 formed on the surface of the device wafer 105. Through-wafer vias 150 are defined passing through the device wafer 105 and terminate on the outside of the package in bond pads often including a layer of copper 155 and a layer of solder 160. One or more of the through-wafer vias 150 may be in electrical communication with the acoustic wave device 110 through a conductive trace 165 defined within the cavity 125.

The package 100 of FIG. 1 is not ideal. Due to process limitations with the plating, the features are large. The minimum width of the standoffs 120, 130 is about 20 μm. The plated Cu has significant thickness variation, so should be planarized before adding the Sn, which can make the Cu—Sn interface prone to voids. Voiding that may occur at the Sn—Cu interface breaks the hermetic seal of the Au—Sn solder bond. Cu diffuses readily into Sn at low temperatures and the intermetallic compounds formed from the Cu and Sn can interfere with bonding to the Au on the device wafer. This limits the process range for bonding. Finally, the Cu column or ring height cannot be reduced below about 15 μm due to metrology limitations. This interferes with the goal of reducing the package thickness.

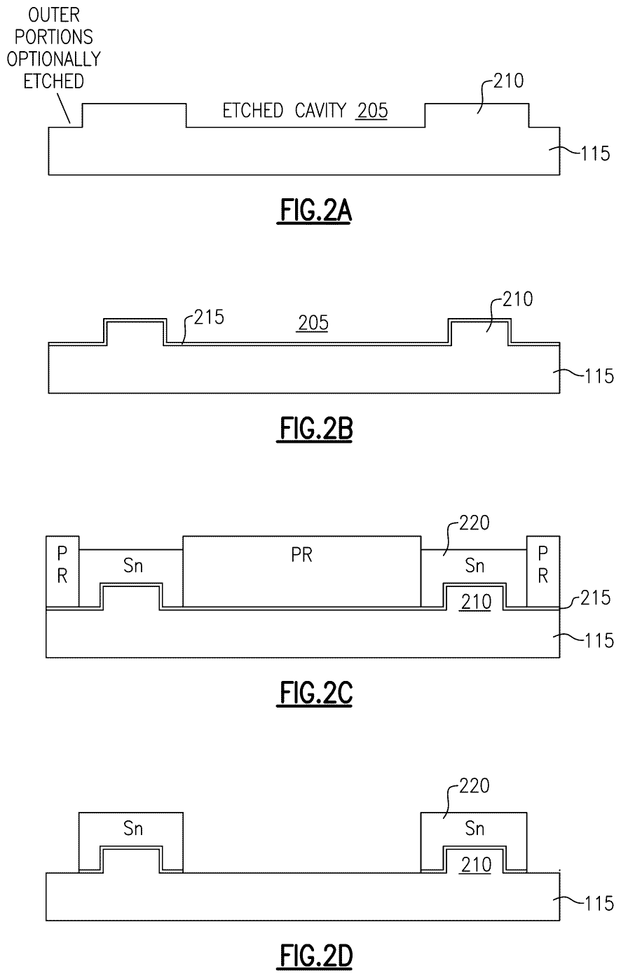

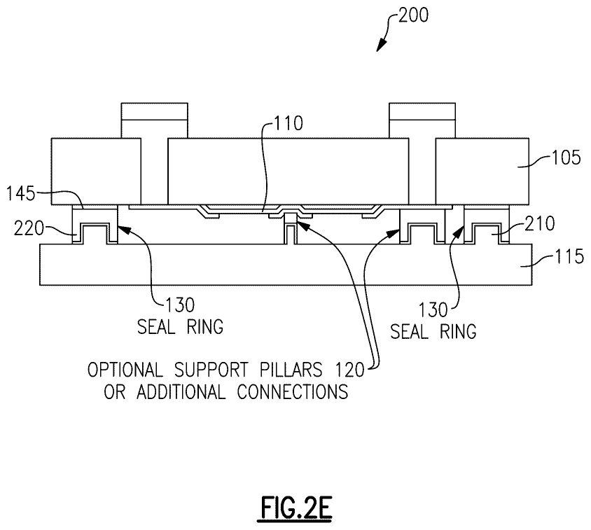

In one embodiment, various undesirable features of the package of FIG. 1 may be improved upon by forming the cap wafer 115 by a different process and to include different forms of standoffs 120, 130. Instead of forming the standoffs 120, 130 on a planar inner surface of the cap wafer 115, a cavity 205 is etched, for example, by wet etching or plasma etching in the cap wafer to define upper inner portions 210 of the standoffs 120, 130 from material of the cap wafer 115 itself, for example, Si and integral with the cap wafer 115. Outer edges of the inner portions 210 of the standoffs 120, 130 may be defined by etching outer portions of the cap wafer 115. This is illustrated in FIG. 2A. The upper inner portions 210 may be, for example, about 6 μm across and about 1-2 μm in height.

A seed layer 215 that may include, for example, a 100 nm thick lower film of Ti and a 300 nm thick upper film of Cu is then deposited, for example, by sputtering on the lower surface of the cap wafer 115 including within the cavity 205 and on the upper inner portions 210 of the standoffs 120, 130 as illustrated in FIG. 2B (seed layers of Ti and Cu not shown separately).

Layers 220 of a metal, for example, Sn are then deposited, for example, by electroplating, sputtering or evaporative deposition on top of and surrounding the upper inner portions 210 of the standoffs 120, 130 with areas in which the Sn is not to be deposited blocked by photoresist PR as illustrated in FIG. 2C. The Sn layers may be, for example, between about 10 μm and about 15 μm wide with heights of between about 1 μm and about 3 μm, although these ranges should be considered only examples and not be limiting.

The photoresist is then removed and the portion of the seed layer 215 not under the Sn layers 220 is removed, for example, by wet etching to result in the cap wafer shown in FIG. 2D.

The cap wafer 115 is then bonded to a device wafer 105 in a similar manner as in the formation of the package 100 by contacting the Sn layers 220 with layers of Au on the surface of the device wafer 105 and bonding the Sn layers 220 on the cap wafer 115 to the Au layers 145 on the device wafer 105 by transient liquid phase bonding to result in a completed package 200 as illustrated in FIG. 2E. In other embodiments the layers 220 of Sn and the layers 145 of Au may be replaced with layers of other pairs of metals capable of forming transient liquid phase bonds with each other. Due to the reduced height and width of the standoffs 120, 130 of the package 200 as compared to those of package 100, package 200 may be both thinner and have a smaller surface area than package 100.

In some embodiments, multiple packaged acoustic wave devices as disclosed herein may be combined into a filter, for example, an RF ladder filter such as that schematically illustrated in FIG. 3 and including a plurality of series resonators R1, R3, R5, R7, and R9, and a plurality of parallel resonators R2, R4, R6, and R8. In various embodiments, the series and/or parallel resonators may be any one or a combination of, for example, SAW resonators, temperature-compensated SAW (TCSAW) resonators, multilayer piezoelectric substrate SAW (MPS-SAW) resonators, BAW resonators, etc. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include acoustic wave devices or resonators, for example, duplexers, baluns, etc., may also be formed including examples of packaged acoustic wave resonators as disclosed herein.

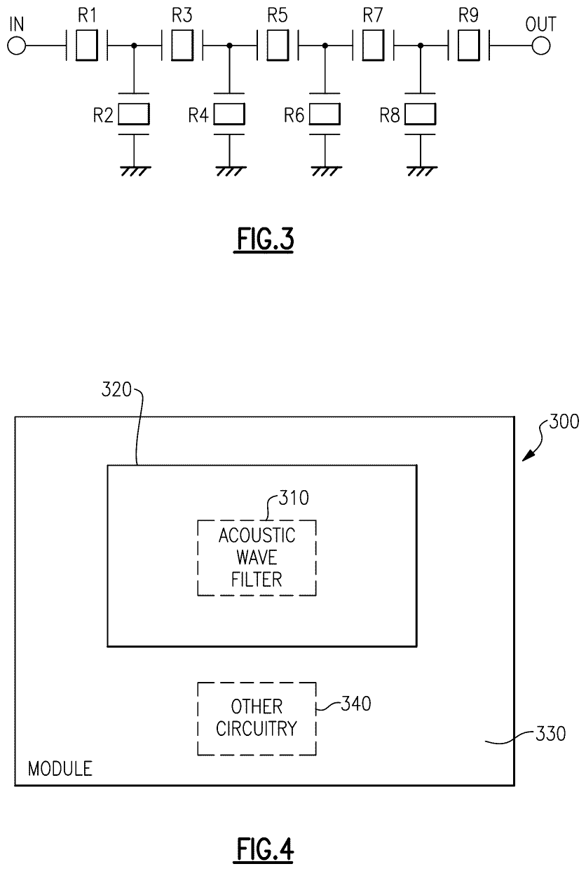

Packaged acoustic wave resonators as discussed herein can be implemented in a variety of packaged modules. Some example packaged modules will now be discussed in which any suitable principles and advantages of the packaged acoustic wave resonators discussed herein can be implemented. FIGS. 4, 5, and 6 are schematic block diagrams of illustrative packaged modules and devices according to certain embodiments.

As discussed above, embodiments of the packaged acoustic wave resonators can be configured as or used in filters. In turn, a filter using one or more acoustic wave resonators may be incorporated into and packaged as a module that may ultimately be used in an electronic device, such as a wireless communications device, for example. FIG. 4 is a block diagram illustrating one example of a module 300 including a filter 310 formed of acoustic wave resonators (an acoustic wave filter 310), which, as discussed above, may include any one or a combination of, for example, SAW resonators, TCSAW resonators, MPS-SAW resonators, BAW resonators, etc. The acoustic wave filter 310 may be implemented on one or more die(s) 320. The packaged module 300 includes a packaging substrate 330 that is configured to receive a plurality of components, including the die 320. The die 320 may be flip-chip mounted on the packaging substrate 330. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the acoustic wave filter 310 can be used in a wide variety of electronic devices. For example, the acoustic wave filter 310 can be used in an antenna duplexer, which itself can be incorporated into a variety of electronic devices, such as RF front-end modules and communication devices.

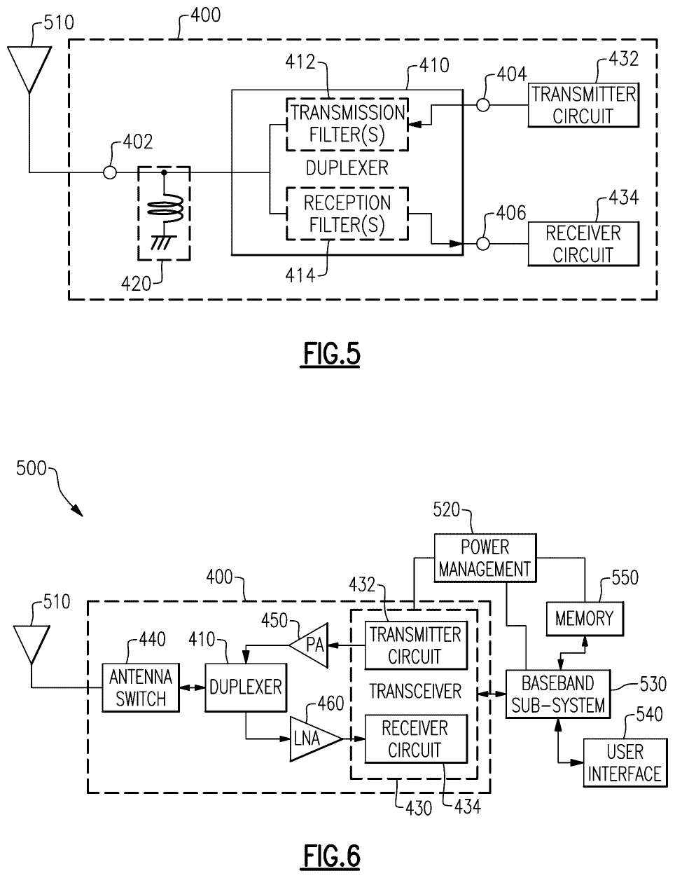

Referring to FIG. 5, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the acoustic wave filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 5, however in other embodiments these components may be integrated into a common transceiver circuit or module. As will be appreciated by those skilled in the art, the front-end module 400 may include other components that are not illustrated in FIG. 5 including, but not limited to, switches, electromagnetic couplers, amplifiers, processors, and the like.

FIG. 6 is a block diagram of one example of a wireless device 500 including the antenna duplexer 410 shown in FIG. 5. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 5. The front-end module 400 includes the duplexer 410, as discussed above. In the example shown in FIG. 6 the front-end module 400 further includes an antenna switch 440, which can be configured to switch between different frequency bands or modes, such as transmit and receive modes, for example. In the example illustrated in FIG. 6, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 5.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 6, the front-end module 400 may further include a low noise amplifier module 460, which amplifies received signals from the antenna 510 and provides the amplified signals to the receiver circuit 434 of the transceiver 430.

The wireless device 500 of FIG. 6 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A package for an acoustic wave device, the package comprising:
a cap wafer having a cavity defined in a lower surface thereof, outside walls of the cavity defining inner edges of an inner portion of a seal ring formed integral with the cap wafer;
a portion of a layer of a first metal disposed on and around the inner portion of the seal ring; and
a device wafer including the acoustic wave device and a layer of a second metal, a portion of the layer of the second metal bonded to the portion of the layer of the first metal to define the seal ring, the cavity surrounding the acoustic wave device and hermetically sealed by the cap wafer, device wafer, and seal ring.

2. The package of claim 1 wherein the seal ring has a width of between 10 μm and 15 μm.

3. The package of claim 1 wherein the seal ring has a height of between 1 μm and 3 μm.

4. The package of claim 1 wherein the portion of the layer of the first metal and the portion of the layer of the second metal are bonded to one another with transient liquid phase bonds.

5. The package of claim 1 wherein the first metal is Sn and the second metal is Au.

6. The package of claim 1 further comprising a support pillar, an inner portion of the support pillar formed integral with the cap wafer and a second portion of the layer of the first metal, the second portion of the layer of the first metal disposed on and around the inner portion of the support pillar, the support pillar extending between the cap wafer and a second portion of the layer of the second metal disposed on the device wafer.

7. The package of claim 1 further comprising a seed layer including Ti and Cu disposed on the inner portion of the seal ring between the inner portion of the seal ring and the portion of the layer of the first metal.

8. An acoustic wave filter including the package of claim 1.

9. An electronic module including the acoustic wave filter of claim 8.

10. An electronic device including the electronic module of claim 9.

11. A method of packaging an acoustic wave device, the method comprising:
etching a cavity in a lower surface of a cap wafer, outside walls of the cavity defining edges of an inner portion of a seal ring formed integral with the cap wafer;
depositing a portion of a layer of a first metal on and around the inner portion of the seal ring; and
bonding the portion of the layer of the first metal to a portion of a layer of a second metal disposed on an upper surface of a device wafer including the acoustic wave device, the bonded portions of the layers of the first metal and second metal defining the seal ring, the cavity surrounding the acoustic wave device and hermetically sealed by the cap wafer, device wafer, and seal ring.

12. The method of claim 11 wherein the seal ring is formed with a width of between 10 μm and 15 μm.

13. The method of claim 11 wherein the seal ring is formed with a height of between 1 μm and 3 μm.

14. The method of claim 11 wherein bonding the portion of the layer of the first metal to the portion of the layer of the second metal includes bonding the portions of the layers of the first and second metals with transient liquid phase bonds.

15. The method of claim 11 further comprising forming a support pillar, an inner portion of the support pillar being formed integral with the cap wafer and a second portion of the layer of the first metal, the second portion of the layer of the first metal deposited on and around the inner portion of the support pillar, the support pillar extending between the cap wafer and a second portion of the layer of the second metal disposed on the device wafer.

16. The method of claim 11 further comprising forming an acoustic wave filter including the acoustic wave device.

17. The method of claim 16 further comprising forming an electronic module including the acoustic wave filter.

18. The method of claim 17 further comprising forming an electronic device including the electronic module.

19. The method of claim 11 further comprising depositing a seed layer including Ti and Cu on the inner portion of the seal ring.

20. The method of claim 19 wherein the portion of the layer of the first metal is deposited on the seed layer.
